(19) United States
(12) Patent Application Publication
(10) Pub. No.: US 2011/0312112 A1
(43) Pub. Date: Dec. 22, 2011

(54) LIGHT EMITTING DIODE

(75) Inventors: Hung-Tse Chen, Hsinchu County (TW); Ko-Ming Chen, Taoyuan Hsien (TW)

(73) Assignee: WALSIN LIHWA CORPORATION, Taoyuan County (TW)

(21) Appl. No.: 13/219,478

(22) Filed: Aug. 26, 2011

Related U.S. Application Data
(62) Division of application No. 12/242,947, filed on Oct. 1, 2008.

(30) Foreign Application Priority Data
Jul. 23, 2008 (TW) 097127948

(51) Int. Cl. H01L 33/58

(52) U.S. Cl. 438/29; 257/E33.074

(57) ABSTRACT

A light emitting diode having a substrate, an electron injection layer, an active layer, a hole injection layer, a first pad electrically connected to the hole injection layer, and a second pad electrically connected to the electron injection layer. The hole injection layer includes an activated region and a patterned non-activated region. The first pad is disposed upon the non-activated region and the first pad and the non-activated region are overlapping in the vertical direction.

### BACKGROUND OF THE INVENTION

1. Field of the Invention

The present invention is related to a light emitting diode (LED) and a method of manufacturing the same, and particularly, to a LED capable of solving problems of current crowding effect and method of manufacturing the same.

2. Description of the Prior Art

The emission of LED is resulted from the band gap energy released by recombination of the electrons and the holes in the semiconductor materials. LED has advantages of small size, long life-span, low driving voltage, low energy consumption, short reaction time, and anti-vibration, and so that, LED is popularly used in display devices or light units for illumination in our daily life.

In order to increase LED's efficiency and brightness, current spreading in the LED is a significant factor. Please refer to FIG. 1. FIG. 1 is a schematic diagram illustrating a conventional LED 10. The LED 10 is formed on a substrate 19, including an n-type semiconductor layer 18, an active layer 16, and a p-type semiconductor layer 14. A p-type electrode 12 is disposed on the p-type semiconductor layer 14, and the p-type electrode 12 is electrically connected to the p-type semiconductor layer 14. The n-type semiconductor layer 18 is electrically connected to an n-type electrode 20. Since the LED 10 is required to have a larger size and higher brightness, the driving current for the LED 10 is consequently increased. The current injects the LED 10 from the p-type electrode 12, goes down through the p-type semiconductor layer 14, the active layer 16, and the n-type semiconductor layer 20, and eventually arrives at the n-type electrode 20. However, the increased current results in non-homogenous distribution of the current in the LED 10. As shown in FIG. 1, the current injected from the p-type electrode 12 is crowded within in a region under the p-type electrode 12 without spreading out. This is so called “current crowding effect.” The current crowding effect diminishes the emission region of the LED and the efficiency of the LED.

To solve the problem of the current crowding effect, a component is added under the p-type electrode to force the current to spread out. Please refer to FIG. 2. FIG. 2 shows another conventional LED 10, which has the same elements and uses the same notation as those shown in FIG. 1. As shown in FIG. 2, a current diffusion layer 17 made of indium tin oxide (ITO) is formed between the p-type electrode and the p-type semiconductor 14. A current blocking layer 22 made of SiO₂ is formed in the p-type semiconductor layer 14 under the p-type electrode 12. Since SiO₂ is an insulating material, the current injected into the p-type electrode 12 is forced to flow laterally rather than limited within the region under the p-type electrode 12. However, the formation of the current blocking layer 22 requires extra fabrication processes. For example, after the thin films, including the n-type semiconductor layer 18, the active layer 16, and the p-type semiconductor layer 14, are formed, a lithography, an etch process, and a deposition process are performed to form the current blocking layer 22. Therefore, the formation of the current blocking layer 22 not only increases the complexity of the LED fabrication process, but also increases the difficulty thereof.

However, several problems need to be solved, such as non-homogeneous distribution of the current and the light emission, and the problems of heat dispersal. In addition, the tendency of LED is to reduce power loss, to increase efficiency and brightness of the LED, and to overcome the heat dispersal resulting from increase of brightness. Theses are the challenges of the current LED industry.

### SUMMARY OF THE INVENTION

The present invention discloses an LED and the method of manufacturing the same to overcome the low efficiency of light emission resulting from current crowding effect.

According to the present invention, an LED is provided. The LED includes a substrate, an electron injection layer, an active layer, and a hole injection layer. The hole injection layer is electrically connected to a first pad, and a current diffusion layer is optionally disposed between the hole injection layer and the first pad. The electron injection layer is disposed on the substrate, and the hole injection layer is disposed on the active layer. The hole injection layer has an activated region and a patterned non-activated region. The first pad of the LED is overlapped with the non-activated region in the vertical direction.

In addition, the present invention further provides a method of forming an LED. A substrate is provided, and an electron injection layer, an active layer, and a hole injection layer are sequentially formed on the substrate. A patterned mask is provided as a shielding mask. A light source is provided to illuminate the mask and the hole injection layer to transfer the pattern of the mask to the hole injection layer and to activate a portion of the hole injection layer without shielding of the mask. Therefore, an activated region and a non-activated region are defined on the hole injection layer. A current diffusion layer is formed on the hole injection layer. A first pad is formed and electrically connected to the hole injection layer. The first pad is overlapped with the patterned non-activated region in the vertical direction.

The hole injection layer of the LED of the present invention is partially activated by a laser to define the activated region and the patterned non-activated region. The patterned non-activated region has a higher contact resistance (or a lower hole carrier concentration) than that of the activated region. As a result, the current from the first pad hardly goes downward but spreads out to form a homogeneous current. In addition, the LED of the present invention is formed without extra etch process or extra deposition process so that the complexity and the difficulty of the fabrication process are reduced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a conventional LED.

FIG. 2 is a schematic diagram illustrating another conventional LED.

FIG. 3 through FIG. 6 are schematic diagrams illustrating an LED and a method for manufacturing the same according to a preferred embodiment of the present invention.

FIG. 7a and FIG. 7b are schematic diagrams illustrating the current path of a respective LED.

FIG. 8a and FIG. 8b are schematic diagrams illustrating a LED according to another preferred embodiment of the present invention.

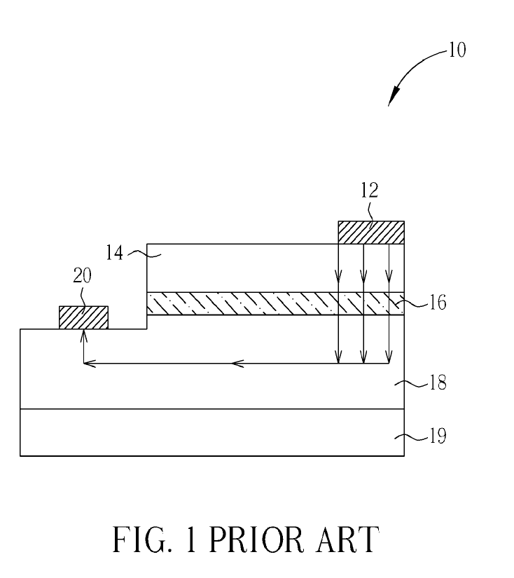

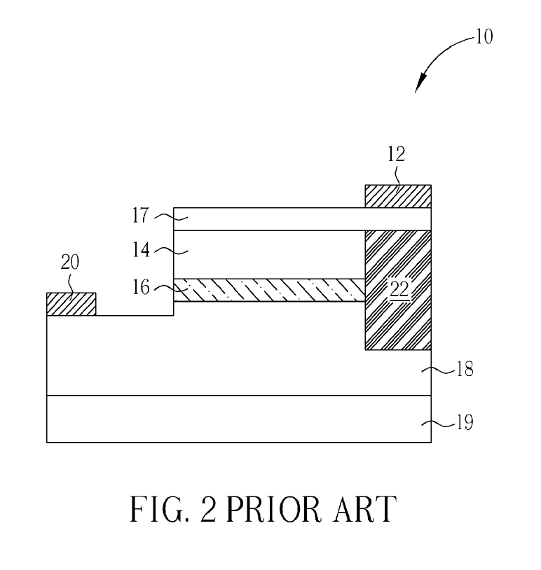

### DETAILED DESCRIPTION

In the following detailed description, reference is made to the accompanying drawings, which form a part of this application. The drawings show, by way of illustration, specific embodiments in which the invention may be practiced. It is to be understood that other embodiments may be utilized and structural changes may be made without departing from the scope of the present invention.

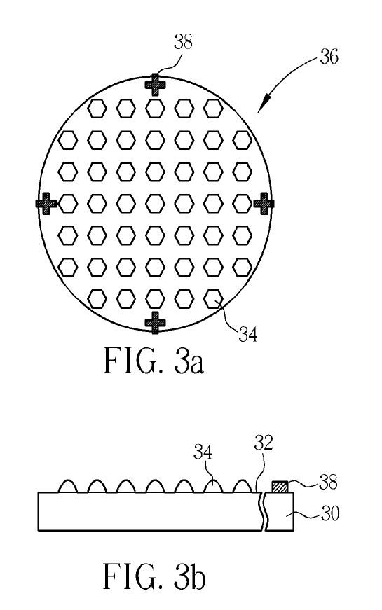

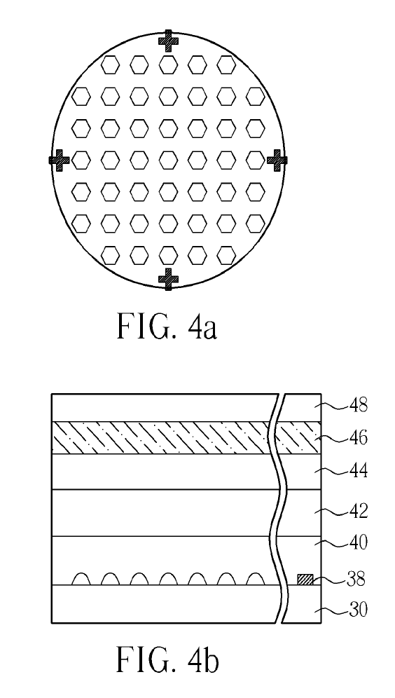

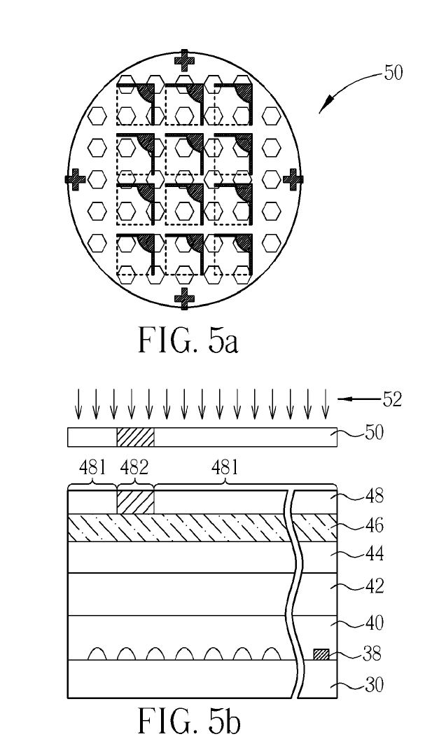

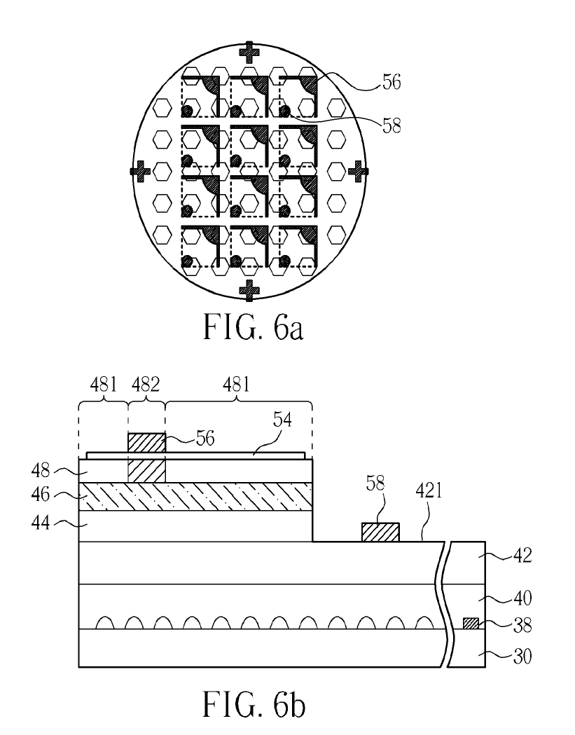

Please refer to FIG. 3 through FIG. 6, which are schematic diagrams illustrating an LED and a method for manufacturing the same according to a preferred embodiment of the present invention. FIG. 3a, FIG. 4a, FIG. 5a, and FIG. 6a are top-view diagrams of the LED of the present invention. FIG. 3b, FIG. 4b, FIG. 5b, and FIG. 6b are sectional diagrams of the LED of the present invention. Please refer to FIG. 3a and FIG. 3b. A substrate 30 is provided and the substrate 30 of the present embodiment may be an insulating substrate, such as a sapphire substrate, a GaN substrate, a Si substrate, or a ZnO substrate. A substrate patterning process is performed, such as a dry etch process to etch the substrate 30, to form a plurality of protrusions 34 on a top surface 32 of the substrate 30. For example, each protrusion 34 is knob of a hexagon shape. The protrusions 34 are arranged as a scattering pattern 36. The shape of the protrusion 34 is not limited to the hexagon-shaped knob shown in the present embodiment, but other shapes are allowable. The scattering pattern 36 is not limited to the 2D matrix shown in the present embodiment. The scattering pattern may be a strip or a texture surface which is capable of improving light emission efficiency. In addition, when the substrate patterning process is performed, a plurality of alignment marks 38 may be simultaneously formed on the top surface 32 of the substrate 30 for correction and alignment in the following process.

As shown in FIG. 4a and FIG. 4b, a buffer layer 40, an electron injection layer 42, an active layer 44, a hole transport layer 46, and a hole injection layer 48 are sequentially formed on the substrate 30. The buffer layer 40 may be an AlN thin film grown in low temperature, a GaN thin film, or other thin film which has a lattice structure matching with the substrate 30 and the electron injection layer 42. The electron injection layer 42 and the hole injection layer 48 are transparent thin film, including GaN, GaP, SiC, ZnO, MgO, Si, or GaAs. The materials of the electron injection layer 42 and the hole injection layer 48 are electrically corresponded, and have good carrier restriction ability or good photo restriction ability. For example, the electron injection layer 42 of the present invention is a n-type GaN thin film, and the hole injection layer 48 is a p-type GaN thin film electrically corresponded to the electron injection layer 42. The active layer 44 disposed between the electron injection layer 42 and the hole injection layer 48 may be a multiple quantum well (MQW) or a double-heterostructure (DH). Furthermore, the formation of the hole transport layer 46 disposed between the hole injection layer 48 and the active layer 44 is optional. The material of the hole transport layer 46 may include a p-type AlGaN thin film that the hole transport layer 46 acts as a spacer for modulating the hole mobility and increasing recombination of the electron and the hole in the active layer 44.

Please refer to FIG. 5a and FIG. 5b. A patterned mask 50 is provided and aligned with the substrate 30 using the alignment marks 38 formed on the substrate 30. A light source 52 is provided, such as a laser or a light source capable of providing partial activation by heat or radiation, to illuminate the mask 50 and the hole injection layer 48. The pattern of the mask 50 is transferred to the hole injection layer 48. Consequently, a portion of the hole injection layer 48 without shielding of the mask 50 is activated and an activated region 481 is defined. On the other hand, another portion of the hole injection layer 48 covered by the mask 50 is defined as a patterned non-activated region 482. For example, the present invention uses laser as the light source 52 to activate and to pattern the hole injection layer 48. The power density of the laser is between 200 and 1500 mJ/cm², preferably between 500 and 700 mJ/cm². The pulse time of the laser is approximately between 10 and 300 ns, and 20 ns is preferable. The frequency of the laser is between 1 and 500 Hz, and 300 Hz is preferable. The wavelength of the laser is approximately between 200 and 1200 nm, and 248 nm or 308 nm is preferable. The wavelength of the laser is not limited to the present embodiment. Furthermore, a plurality of L-shaped patterns is disposed on the mask 50, shown in FIG. 5a. Each L-shaped pattern includes a round center and two perpendicular arranged wings expanding from the center. After the illumination of the laser, a plurality of patterned non-activated regions 482 having an L shape is formed on the hole injection layer 48. The hole carrier concentration of the patterned non-activated region 482 is less than 10¹⁶ cm⁻³, and the carrier mobility is less than 1 cm²/Vs. The contact resistance of the patterned non-activated region 482 is higher than 10⁻² Ohmic/cm². On the contrary, the activated region 481 activated by the laser has a hole carrier concentration of more than 10¹⁷ cm⁻³. The carrier mobility of the activated region 481 is increased to more than 20 cm²/Vs and the contact resistance thereof is decreased from 10⁻² Ohmic/cm² to less than 10⁻³ Ohmic/cm². As a result, by means of laser illumination and the usage of the mask 50, the hole carrier concentration and the carrier mobility of the activated region 481 increase by more than one order in contrast to the patterned non-activated region 482 after laser illumination. In addition, the contact resistance of the activated region 481 is decreased by more than one order.

As shown in FIG. 6a and FIG. 6b, a current diffusion layer 54 is formed on a surface of the hole injection layer 48 having the activated region 481 and the patterned non-activated region 482 therein. The current diffusion layer 54 may be a transparent conductive layer, such as an ITO layer. An etch process is performed to etch a portion of the hole injection layer 48, a portion of the hole transport layer 46, and a portion of the active layer 44 to expose a surface 421 of a portion of the electron injection layer 42. A first pad 56 is formed on the current diffusion layer 54 and the first pad 56 is electrically connected to the hole injection layer 48. A second pad 58 is formed on the exposed surface 421 of the electron injection layer 42, and the second pad 58 is electrically connected to the electron injection layer 42. The formation of the first pad 56 uses the alignment marks 38 for alignment. An evaporation process or a sputtering process is performed to deposit Au, Ge, Ni, Cr, Pt, or combinations thereof on the current diffusion layer 54. The position and the shape of the first pad 56 correspond to the patterned non-activated region 482 that the patterned non-activated region 482 is disposed under the first pad 56 and is overlapped with the patterned non-activated region in the vertical direction.

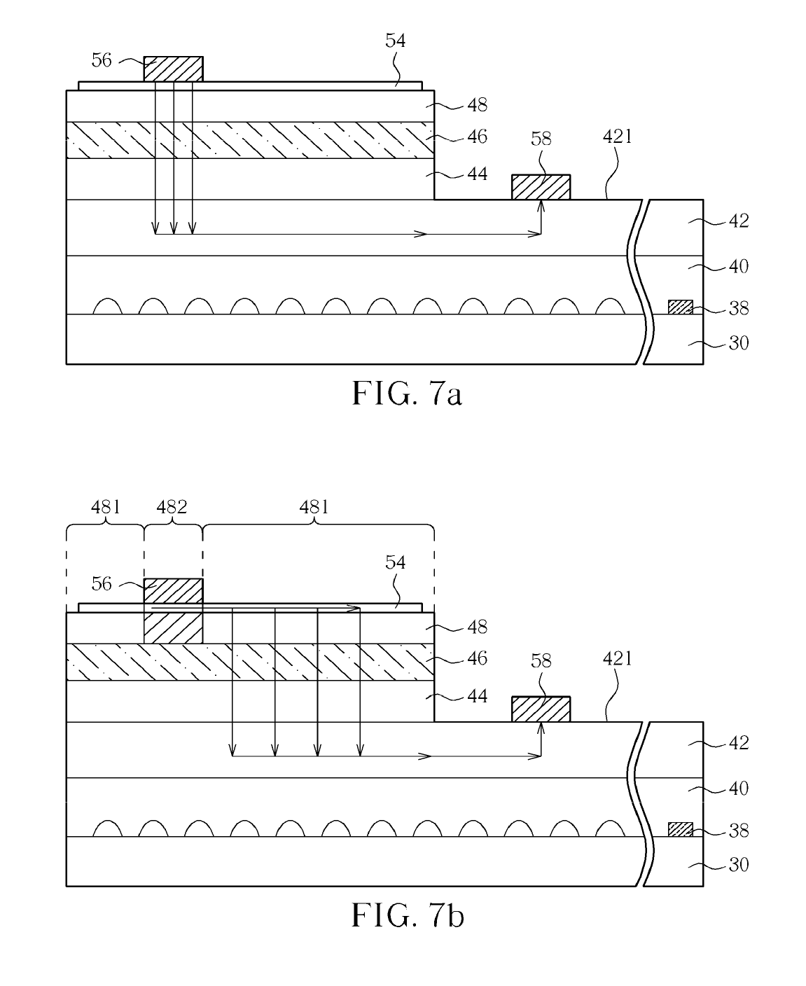

Accordingly, the formation of the LED utilizes the alignment mark 38 for alignment. Subsequent to the formation of the patterned non-activated region 482 in the hole injection layer 48, the first pad 56 is formed and disposed accurately above the pattern non-activated region 482 using the alignment mark 38 for alignment. Please refer to FIG. 7a and FIG. 7b, which are schematic diagrams illustrating the current path of a respective LED. The LED shown in FIG. 7a does not have the activated region 481 and the patterned non-activated region 482. The LED of the present invention is shown in FIG. 7b that the LED has the patterned non-activated region 482 of lower hole carrier concentration disposed under the first pad 56. As shown in FIG. 7a, the current injected from the first pad 56 goes downward without spreading out and arrives at the electron injection layer 42. On the other hand, the current injected from the first pad 56 shown in FIG. 7b spreads out because the patterned non-activated region 482 disposed under the first pad 56 has a higher contact resistance than that of the activated region 481 and so that the current passes through the activated region 481 of a lower contact resistance. The injected current initially spreads out laterally in the current diffusion layer 54 and passes through the active layer 44 and the electron injection layer 42. In addition, the LED of the present invention prevents light emission from being limited by the first pad 56, and so that, the LED of the present invention solves the problem of low illumination efficiency resulting from the current crowding effect.

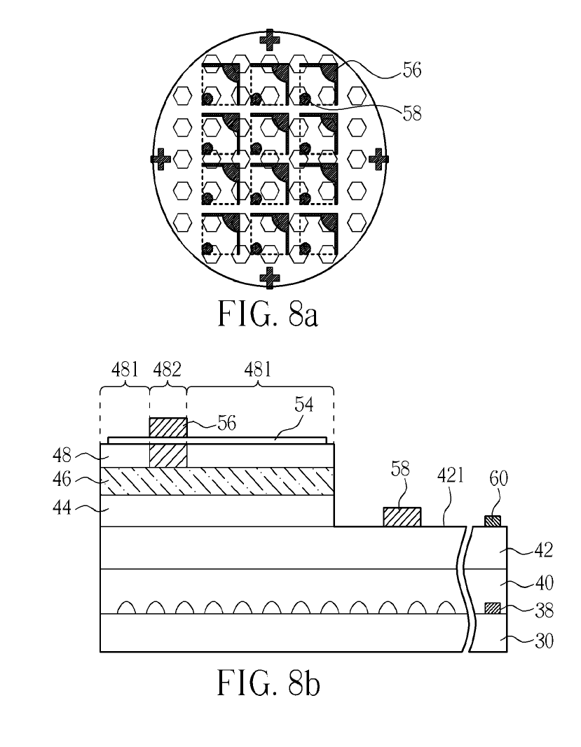

The method of forming the LED of the present invention is not limited to the aforementioned embodiment. Please refer to FIG. 8a and FIG. 8b, which are schematic diagrams illustrating a LED according to another preferred embodiment of the present invention. FIG. 8a is a top-view diagram of the LED of the present embodiment, and FIG. 8b is a sectional diagram of the LED of the present embodiment. As shown in FIG. 8a and FIG. 8b, the alignment mark may be formed after the formation of the buffer layer 40, the electron injection layer 42, and the active layer 44, and the hole injection layer 46. An etch process is performed to etch a portion of the hole injection layer 48, a portion of the hole transport layer 46, and a portion of the active layer 44 to expose a surface 421 of a portion of the electron injection layer 42, and at least an alignment mark 60 is formed on the exposed surface 421 for alignment in the follow processes. For example, the formation of the patterned non-activated region 482 in the hole injection layer 48 and the formation of the first pad 56 may use the alignment mark 60 for alignment. In addition, the LED of the present invention may have both the alignment mark 38 disposed on the substrate 30 and the alignment mark 60 disposed on expose surface 421 of the electron injection layer 42 for alignment.

Moreover, the substrate may be a conductive substrate including SiC, Si, GaN or GaAs, and so that the second pad is formed on the other surface of the substrate opposite to the electron injection layer. As a result, a vertical structured LED is formed and is used as a light source of large area.

The LED of the present invention uses a laser to partially activate the hole injection layer and to define the activated region and the patterned non-activated region in the hole injection layer. The patterned non-activated region has a larger contact resistance and a lower hole carrier concentration than that of the activated region which is capable of preventing current from directly passing downward from the first pad, and so that the current is homogeneously presented in the LED. Moreover, no extra etch process or deposition process is required to form the LED of the present invention. The complexity and the difficulty of the fabrication process are therefore reduced.

Those skilled in the art will readily observe that numerous modifications and alterations of the device and method may be made while retaining the teachings of the invention.

1. (canceled)

2. (canceled)

3. (canceled)

4. (canceled)

5. (canceled)

6. (canceled)

7. (canceled)

8. A method of forming a light emitting diode (LED), comprising:
providing a substrate and sequentially forming an electron injection layer, an active layer, and a hole injection layer;
providing a patterned mask and using a light source to illuminate the patterned mask and the hole injection layer for transferring the pattern from the mask to the hole injection layer, activating a portion of hole injection layer without coverage of the patterned mask, and defining an activated region and a patterned non-activated region on the hole injection layer, wherein the light source comprises a laser; and
forming a first pad electrically connected to the hole injection layer, wherein the first pad overlaps the patterned non-activated region of the hole injection layer vertically.

9. The method of claim 8, further comprising a substrate patterning process to form a scattering pattern on a surface of the substrate prior to the formation of the electron injection layer, the active layer, and the hole injection layer.

10. The method of claim 9, further comprising forming an alignment mark on the surface of the substrate.

11. The method of claim 8, further comprising performing an etch process to etch a portion of the hole injection layer and a portion of the active layer to expose a surface of a portion of the electron injection layer before a portion of the electron injection layer is activated.

12. The method of claim 11, further comprising forming at least an alignment mark on the exposed surface of the electron injection layer.

13. The method of claim 11, further comprising forming a second pad on the exposed surface of the electron injection layer, the second pad being electrically connected to the electron injection layer.

14. The method of claim 8, wherein the patterned non-activated region has a contact resistance higher than that of the activated region.

15. The method of claim 8, wherein the patterned non-activated region has a hole carrier concentration less than that of the activated region.

16. (canceled)

17. The method of claim 8, wherein the laser has a power density between 200 and 1500 mJ/cm.sub.2.

18. The method of claim 8, further comprising forming a hole transport layer on the active layer prior to the formation of the hole injection layer.

19. The method of claim 8, further comprising forming a buffer layer on the substrate prior to the formation of the electron injection layer.

20. The method of claim 8, further comprising forming a current diffusion layer on the hole injection layer prior to the formation of the first pad.

21. A method of forming a light emitting diode (LED), comprising:
providing a substrate and sequentially forming a plurality of layers including a hole injection layer;
providing a patterned mask and using a light source to illuminate the patterned mask and the hole injection layer for transferring the pattern from the mask to the hole injection layer, wherein the light source comprises a laser;
activating a portion of hole injection layer without coverage of the patterned mask; and
defining an activated region and a patterned non-activated region on the hole injection layer.

22. The method of claim 21, wherein the plurality of layers further comprises an electron injection layer and an active layer.

23. The method of claim 21, further comprising forming a first pad electrically connected to the hole injection layer, wherein the first pad overlaps the patterned non-activated region of the hole injection layer vertically

24. The method of claim 22, further comprising a substrate patterning process to form a scattering pattern on a surface of the substrate prior to the formation of the electron injection layer, the active layer, and the hole injection layer.

25. The method of claim 22, further comprising performing an etch process to etch a portion of the hole injection layer and a portion of the active layer to expose a surface of a portion of the electron injection layer before a portion of the electron injection layer is activated.

26. The method of claim 22, further comprising forming a hole transport layer on the active layer prior to the formation of the hole injection layer.

27. The method of claim 22, further comprising forming a buffer layer on the substrate prior to the formation of the electron injection layer.

28. The method of claim 23, further comprising forming a current diffusion layer on the hole injection layer prior to the formation of the first pad.
